(19) United States
(12) Patent Application Publication
(10) Pub. No.: US 2025/0261424 A1
(43) Pub. Date: Aug. 14, 2025

(54) SEMICONDUCTOR BACKSIDE CONTACT SPACER ENGINEERING

(71) Applicant: International Business Machines Corporation, Armonk, NY (US)

(72) Inventors: John Christopher Arnold, North Chatham, NY (US); Ruilong Xie, Niskayuna, NY (US); Kisik Choi, Watervliet, NY (US); Tenko Yamashita, Schenectady, NY (US); Mahender Kumar, Clifton Park, NY (US); Ravikumar Ramachandran, Pleasantville, NY (US)

(21) Appl. No.: 18/438,642

(22) Filed: Feb. 12, 2024

(51) Int. Cl. H01L 29/66; H01L 21/8234; H01L 27/088; H01L 29/06; H01L 29/08; H01L 29/423; H01L 29/775; H01L 29/786

(52) U.S. Cl. CPC H10D 64/018; H10D 30/014; H10D 30/43; H10D 30/6735; H10D 30/6757; H10D 62/121; H10D 62/151; H10D 64/017; H10D 84/013; H10D 84/0135; H10D 84/038; H10D 84/83

(57) ABSTRACT

A semiconductor structure is provided. In one embodiment, the semiconductor structure includes a first inner spacer and a second inner spacer disposed on a silicon layer, a third inner spacer disposed on the first inner spacer, a fourth inner spacer disposed on the second inner spacer, a gate region disposed on the silicon layer, and a source/drain region disposed on a backside source/drain contact, where an upper surface of the backside source/drain contact is disposed above a bottom surface of the first inner spacer or the second inner spacer, and where the upper surface of the backside source/drain contact is disposed below an upper surface of the third inner spacer or the fourth inner spacer.

### BACKGROUND

The present disclosure relates to semiconductor backside contact spacer engineering, and more specifically, to forming semiconductor backside source/drain contact spacers that improve semiconductor production processes.

A conventional process for forming backside source/drain contact spacers involves using a single non-stacked spacer layer to create a separation between a silicon layer and a nanosheet located at a source/drain region of a semiconductor structure. The extent of this separation can define permissible margin sizes for forming a backside source/drain contact to maintain functionality of the semiconductor structure. However, using the single, non-stacked spacer layer in this manner requires strict adherence to semiconductor production procedures to form the backside source/drain contact within a limited margin size, which can lead to increased fabrication errors and reduced yield.

### SUMMARY

A semiconductor structure is provided according to one embodiment of the present disclosure. The semiconductor structure includes a first inner spacer and a second inner spacer disposed on a silicon layer, a third inner spacer disposed on the first inner spacer, a fourth inner spacer disposed on the second inner spacer, a gate region disposed on the silicon layer, and a source/drain region disposed on a backside source/drain contact, where an upper surface of the backside source/drain contact is disposed above a bottom surface of the first inner spacer or the second inner spacer, and where the upper surface of the backside source/drain contact is disposed below an upper surface of the third inner spacer or the fourth inner spacer.

A method is provided according to one embodiment of the present disclosure. The method includes forming a set of trenches in a semiconductor structure, forming a first inner spacer and a second inner spacer in the set of trenches, forming a third inner spacer and a fourth inner spacer in the set of trenches, where the third inner spacer is disposed on the first inner spacer, and where the fourth inner spacer is disposed on the second inner spacer, and forming a backside source/drain contact in the set of trenches, where an upper surface of the backside source/drain contact is disposed above a bottom surface of the first inner spacer or the second inner spacer, and where the upper surface of the backside source/drain contact is disposed below an upper surface of the third inner spacer or the fourth inner spacer.

### BRIEF DESCRIPTION OF THE DRAWINGS

FIGS. 1A, 1B, and 1C illustrate a top view and cross-sectional views of a semiconductor structure with increased margins for backside source/drain contacts, according to one embodiment.

FIGS. 2A, 2B, and 2C illustrate a top view and cross-sectional views of a semiconductor structure under fabrication, according to one embodiment.

FIGS. 3A, 3B, and 3C illustrate a top view and cross-sectional views of a semiconductor structure under fabrication, according to one embodiment.

FIGS. 4A, 4B, and 4C illustrate a top view and cross-sectional views of a semiconductor structure under fabrication, according to one embodiment.

FIGS. 5A, 5B, and 5C illustrate a top view and cross-sectional views of a semiconductor structure under fabrication, according to one embodiment.

FIGS. 6A, 6B, and 6C illustrate a top view and cross-sectional views of a semiconductor structure under fabrication, according to one embodiment.

FIGS. 7A, 7B, and 7C illustrate a top view and cross-sectional views of a semiconductor structure under fabrication, according to one embodiment.

FIGS. 8A, 8B, and 8C illustrate a top view and cross-sectional views of a semiconductor structure under fabrication, according to one embodiment.

FIGS. 9A, 9B, and 9C illustrate a top view and cross-sectional views of a semiconductor structure under fabrication, according to one embodiment.

FIGS. 10A, 10B, and 10C illustrate a top view and cross-sectional views of a semiconductor structure under fabrication, according to one embodiment.

FIGS. 11A, 11B, and 11C illustrate a top view and cross-sectional views of a semiconductor structure under fabrication, according to one embodiment.

FIGS. 12A, 12B, and 12C illustrate a top view and cross-sectional views of a semiconductor structure under fabrication, according to one embodiment.

FIGS. 13A, 13B, and 13C illustrate a top view and cross-sectional views of a semiconductor structure under fabrication, according to one embodiment.

FIGS. 14A, 14B, and 14C illustrate a top view and cross-sectional views of a semiconductor structure under fabrication, according to one embodiment.

FIGS. 15A, 15B, and 15C illustrate a top view and cross-sectional views of a semiconductor structure under fabrication, according to one embodiment.

FIGS. 16A, 16B, and 16C illustrate a top view and cross-sectional views of a semiconductor structure under fabrication, according to one embodiment.

FIGS. 17A, 17B, and 17C illustrate a top view and cross-sectional views of a semiconductor structure under fabrication, according to one embodiment.

### DETAILED DESCRIPTION

A semiconductor structure is provided according to one embodiment of the present disclosure. The semiconductor structure includes a first inner spacer and a second inner spacer disposed on a silicon layer, a third inner spacer disposed on the first inner spacer, a fourth inner spacer disposed on the second inner spacer, a gate region disposed on the silicon layer, and a source/drain region disposed on a backside source/drain contact, where an upper surface of the backside source/drain contact is disposed above a bottom surface of the first inner spacer or the second inner spacer, and where the upper surface of the backside source/drain contact is disposed below an upper surface of the third inner spacer or the fourth inner spacer. Advantageously, this improves margin sizes afforded to form backside source/drain contacts, thereby reducing fabrication errors and increasing semiconductor yield.

According to another embodiment of the present disclosure, the gate region is a T-shaped gate region formed by the first inner spacer, the second inner spacer, the third inner spacer, and the fourth inner spacer. Further, the first inner spacer and the second inner spacer are disposed on a same level of the semiconductor structure, and the first inner spacer and the second inner spacer form a bottom region of the T-shaped gate region. Further, the third inner spacer and the fourth inner spacer are disposed on another same level of the semiconductor structure, and the third inner spacer and the fourth inner spacer form a top region of the T-shaped gate region. Further, the top region of the T-shaped gate region is wider than the bottom region of the T-shaped gate region. Advantageously, this can reduce a parasitic capacitance between the T-shaped gate region and the source/drain region, which can further increase the sizing margins afforded to form backside source/drain contacts.

According to another embodiment of the present disclosure, the semiconductor structure further includes another source/drain region disposed on a placeholder, where an upper surface of the placeholder is disposed above a bottom surface of the first inner spacer or the second inner spacer, and where the upper surface of the placeholder is disposed below an upper surface of the third inner spacer or the fourth inner spacer. Further, the placeholder is separated from the T-shaped gate region via the first inner spacer and the third inner spacer. Advantageously, this improves margin sizes afforded to form backside source/drain contacts in place of the placeholder, thereby reducing fabrication errors and increasing semiconductor yield.

According to another embodiment of the present disclosure, the placeholder and the backside source/drain contact are disposed in a backside interlayer dielectric (ILD) layer, the backside ILD layer is disposed on a backside interconnect, a frontside source/drain contact is disposed on the another source/drain region, a frontside ILD layer is disposed on the source/drain region, a self-aligned gate cap, and a plurality of gate spacers, a back-end-of-line interconnect is disposed on the frontside source/drain contact, and a carrier wafer is bonded to the back-end-of-line interconnect. Advantageously, this enables operation and interconnection of the semiconductor structure with an integrated circuit.

A method is provided according to one embodiment of the present disclosure. The method includes forming a set of trenches in a semiconductor structure, forming a first inner spacer and a second inner spacer in the set of trenches, forming a third inner spacer and a fourth inner spacer in the set of trenches, where the third inner spacer is disposed on the first inner spacer, and where the fourth inner spacer is disposed on the second inner spacer, and forming a backside source/drain contact in the set of trenches, where an upper surface of the backside source/drain contact is disposed above a bottom surface of the first inner spacer or the second inner spacer, and where the upper surface of the backside source/drain contact is disposed below an upper surface of the third inner spacer or the fourth inner spacer. Advantageously, this improves margin sizes afforded to form backside source/drain contacts, thereby reducing fabrication errors and increasing semiconductor yield.

According to another embodiment of the present disclosure, the semiconductor structure includes a silicon substrate, a first sacrificial layer disposed on the silicon substrate, wherein the first sacrificial layer includes SiGe25%, a silicon layer disposed on the first sacrificial layer, a silicon etch stop layer disposed on the silicon layer, wherein the silicon etch stop includes SiGe55%, a second sacrificial layer disposed on the silicon etch stop, a first nanosheet layer disposed on the second sacrificial layer, a third sacrificial layer disposed on the first nanosheet layer, a second nanosheet layer disposed on the third sacrificial layer, a fourth sacrificial layer disposed on the second nanosheet layer, and a third nanosheet layer disposed on the fourth sacrificial layer. Further, the first inner spacer and the second inner spacer are formed in the silicon etch stop layer. Further, the third inner spacer and the fourth inner spacer are formed in the second sacrificial layer. Advantageously, this can reduce damage to hardmasks and spacers of the semiconductor structure during etching processes performed to form trenches in the semiconductor structure.

According to another embodiment of the present disclosure, the method further comprises depositing a high-k metal gate material between the first inner spacer and the second inner spacer, and depositing the high-k metal gate material between the third inner spacer and the fourth inner spacer. Further, the high-k metal gate material forms a T-shaped gate region. Further, the backside source/drain contact is isolated from the T-shaped gate region via the second inner spacer and the fourth inner spacer. Further, the high-k metal gate material between the first inner spacer and the second inner spacer forms a bottom region of the T-shaped gate region. Further, the high-k metal gate material between the third inner spacer and the fourth inner spacer forms a top region of the T-shaped gate region. Further, the top region of the T-shaped gate region is wider than the bottom region of the T-shaped gate region. Advantageously, this can reduce a parasitic capacitance between the T-shaped gate region and the source/drain region, which can further increase the sizing margins afforded to form backside source/drain contacts.

Embodiments of the present disclosure improve upon semiconductor production processes by providing multiple, stacked inner spacers between a silicon layer and a nanosheet located at a source/drain region of a semiconductor structure. In one embodiment, the source/drain region is disposed on a backside source/drain contact. An upper surface of the backside source/drain contact can be disposed above a bottom surface of a first inner spacer or the second inner spacer. Further, the upper surface of the backside source/drain contact can be disposed below an upper surface of the third inner spacer or the fourth inner spacer, which are disposed on the first inner spacer and the second inner spacer, respectively. The backside source/drain contact can be isolated from a T-shaped gate region via a stack of inner spacers.

One benefit of the disclosed embodiments is to improve margin sizes (e.g., tolerance for variability) afforded to form backside source/drain contacts, thereby reducing fabrication errors and increasing semiconductor yield. Further, embodiments of the present disclosure can reduce a parasitic capacitance between a gate and a source/drain region, which can further increase the sizing margins afforded to form the backside source/drain contacts.

Descriptions of various embodiments of the present disclosure are presented for purposes of illustration, but are not intended to be exhaustive or limited to the embodiments disclosed. Modifications and variations can be made to embodiments of the present disclosure without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

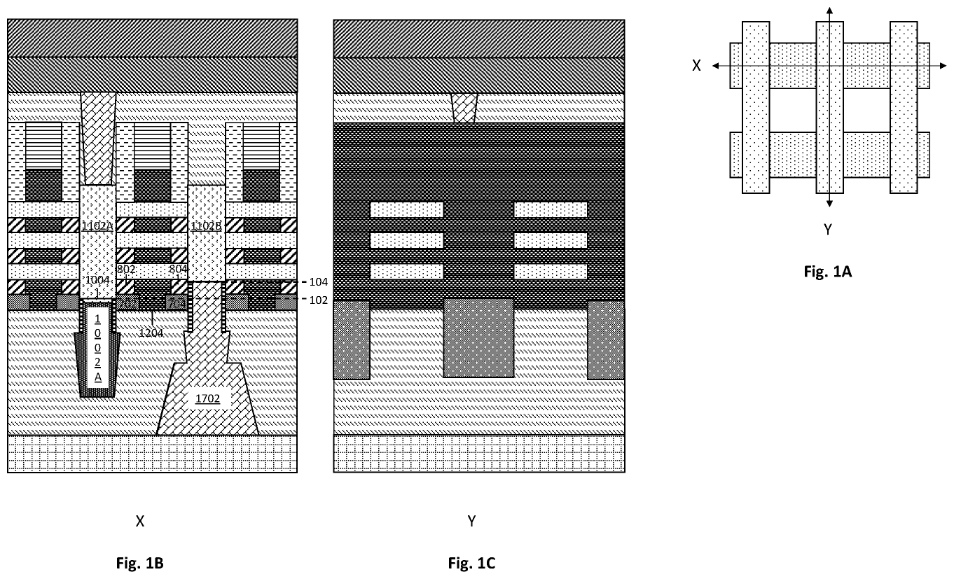

FIGS. 1A, 1B, and 1C illustrate a top view and cross-sectional views of a semiconductor structure with increased margins for backside source/drain contacts, according to one embodiment. FIG. 1A illustrates a top view of the semiconductor structure. In the illustrated embodiment, cross-section indicator X is shown traversing an active region of the semiconductor structure along an x-axis. Cross-section indicator Y is shown traversing a gate region of the semiconductor structure along the y-axis.

FIG. 1B illustrates a cross-section of the semiconductor structure at cross-section indicator X. In the illustrated embodiment, a first source/drain region 1102A is disposed on a placeholder cap layer 1004, which is disposed on a first placeholder 1002A. The first placeholder 1002A can represent a location or pattern of a potential backside source/drain contact. The placeholder cap layer 1004 can reflect a first position level 102 of an upper surface of the first placeholder 1002A. In another embodiment, the placeholder cap layer 1004 is not included, and the first source/drain region 1102A is disposed on the first placeholder 1002A.

A second source/drain region 1102B can be disposed on a backside source/drain contact 1702. An upper surface of the backside source/drain contact 1702 can reflect a second position level 104.

In one embodiment, a distance between the first position level 102 and the second position level 104 represents a margin size (e.g., a size or dimension range) allowed for the formation of an upper surface of the backside source/drain contact 1702 and an upper surface of the potential backside source/drain contact that can be formed at the first placeholder 1002A. Backside source/drain contacts that fall within the margin size can maintain functionality of the semiconductor structure.

The margin size can be determined by the dimensions of stacked inner spacers (e.g., the combined height of a first inner spacer 702 and a third inner spacer 802) disposed on another inner spacer. In one embodiment, a backside source/drain contact falls within the margin size when an upper surface of the backside source/drain contact is disposed between an upper surface and a lower surface of the stacked inner spacers (e.g., an upper surface of the third inner spacer 802 and a lower surface of a first inner spacer 702).

In one embodiment, multiple inner spacers (e.g., the first inner spacer 702, a second inner spacer 704, the third inner spacer 802, and a fourth inner spacer 804) form a T-shaped gate region 1204 between the first placeholder 1002A and the backside source/drain contact 1702. The multiple inner spacers can reduce parasitic capacitance between the T-shaped gate region 1204 and the backside source/drain contact 1702. In another embodiment, the multiple inner spacers form a rectangular-shaped gate region, an inverse T-shaped gate region, or the like, between the first placeholder 1002A and the backside source/drain contact 1702.

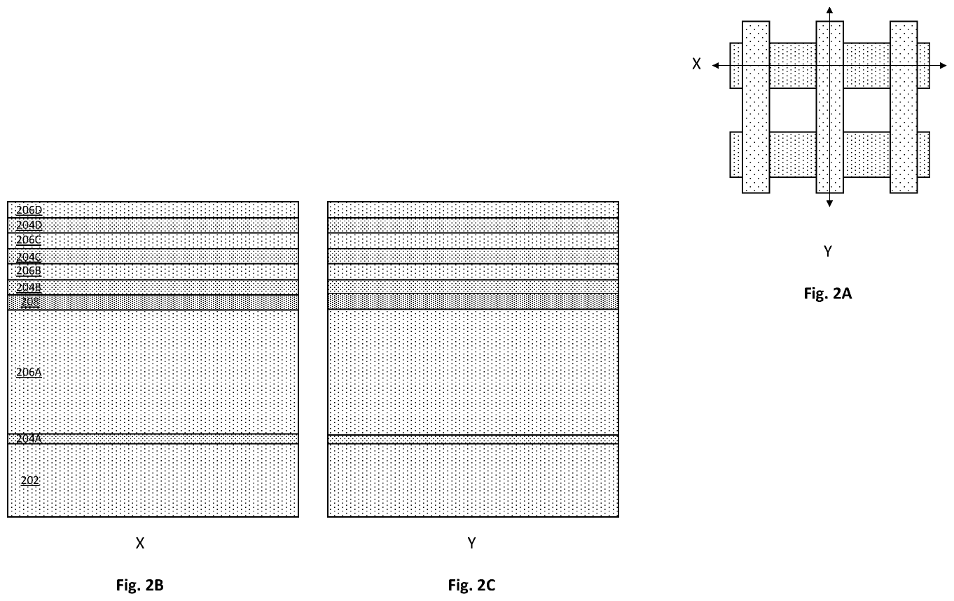

FIG. 1C illustrates a cross-section of the semiconductor structure at cross-section indicator Y. Fabrication processes to form the semiconductor structure of FIGS. 1A-1C are described in FIGS. 2A-17C below.

FIGS. 2A, 2B, and 2C illustrate a top view and cross-sectional views of a semiconductor structure under fabrication, according to one embodiment. FIG. 2A illustrates a top view of the semiconductor structure. In the illustrated embodiment, cross-section indicator X is shown traversing a potential active region of the semiconductor structure along an x-axis. Cross-section indicator Y is shown traversing a potential gate region of the semiconductor structure along the y-axis. FIG. 2B illustrates a cross-section of the semiconductor structure at cross-section indicator X. FIG. 2C illustrates a cross-section of the semiconductor structure at cross-section indicator Y.

In one embodiment, a first layer of the semiconductor structure includes a silicon substrate 202. Additional layers of the semiconductor structure can be grown via epitaxial growth processes.

A second layer (e.g., a sacrificial layer 204A) of the semiconductor structure can be grown on the first layer. A third layer (e.g., a silicon layer 206A) can be grown on the second layer. A fourth layer (e.g., silicon etch stop layer 208) can be grown on the third layer. A fifth layer (e.g., a sacrificial layer 204B) can be grown on the fourth layer. A sixth layer (e.g., a nanosheet layer 206B) can be grown on the fifth layer. A seventh layer (e.g., a sacrificial layer 204C) can be grown on the sixth layer. An eighth layer (e.g., a nanosheet layer 206C) can be grown on the seventh layer. A ninth layer (e.g., a sacrificial layer 204D) can be grown on the eighth layer. A tenth layer (e.g., a nanosheet layer 206D) can be grown on the ninth layer.

The sacrificial layers 204A-204D of the semiconductor structure can include materials such as silicon-germanium (SiGe), or the like. In one embodiment, sacrificial layer 204A includes SiGe25%, silicon etch stop layer 208 includes SiGe55%, and sacrificial layers 204B-204D include SiGe with a Ge % ranging from 20% to 35%. In another embodiment, the sacrificial layer 204A, silicon etch stop layer 208, and sacrificial layers 204B-204D include SiGe with other Ge % concentrations.

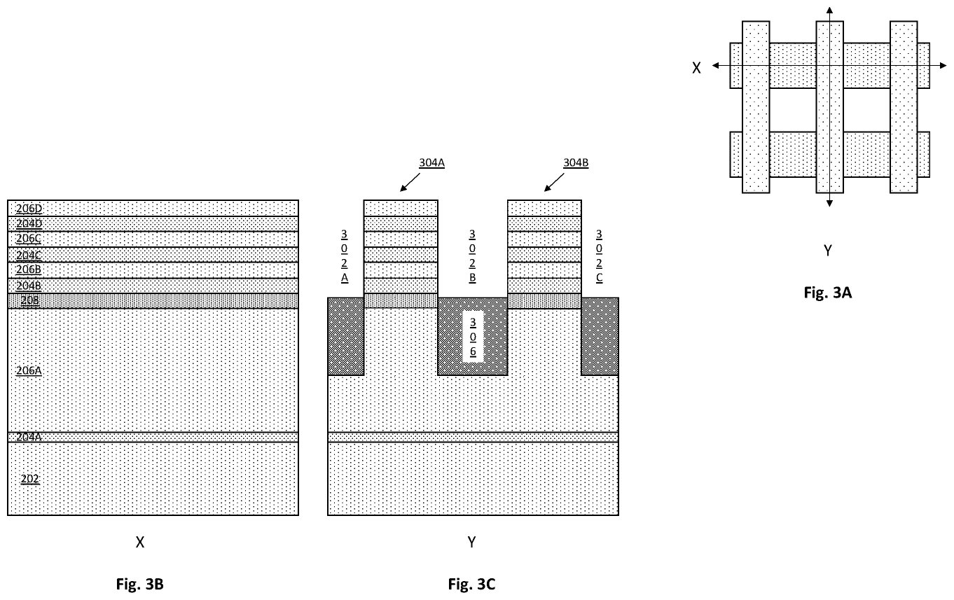

FIGS. 3A, 3B, and 3C illustrate a top view and cross-sectional views of a semiconductor structure under fabrication, according to one embodiment. FIG. 3A illustrates a top view of the semiconductor structure. In the illustrated embodiment, cross-section indicator X is shown traversing a potential active region of the semiconductor structure along an x-axis. Cross-section indicator Y is shown traversing a potential gate region of the semiconductor structure along the y-axis. FIG. 3B illustrates a cross-section of the semiconductor structure at cross-section indicator X. FIG. 3C illustrates a cross-section of the semiconductor structure at cross-section indicator Y.

In one embodiment, a lithography patterning and an etching process are performed to remove portions of layers 3-10 (e.g., portions of the silicon layer 206A, the nanosheet layers 206B-206D, the sacrificial layers 204B-204D, and silicon etch stop layer 208) of the semiconductor structure, which forms a first set of trenches 302A-302C and fin structures 304A-304B.

A shallow trench isolation material 306 can be deposited in the first set of trenches 302A-302C. The shallow trench isolation material 306 can include electrically insulating material such as SiO₂, Si₃N₄, or the like. In one embodiment, the shallow trench isolation material 306 is planarized and recessed to be below a topside of the fifth layer of the semiconductor structure.

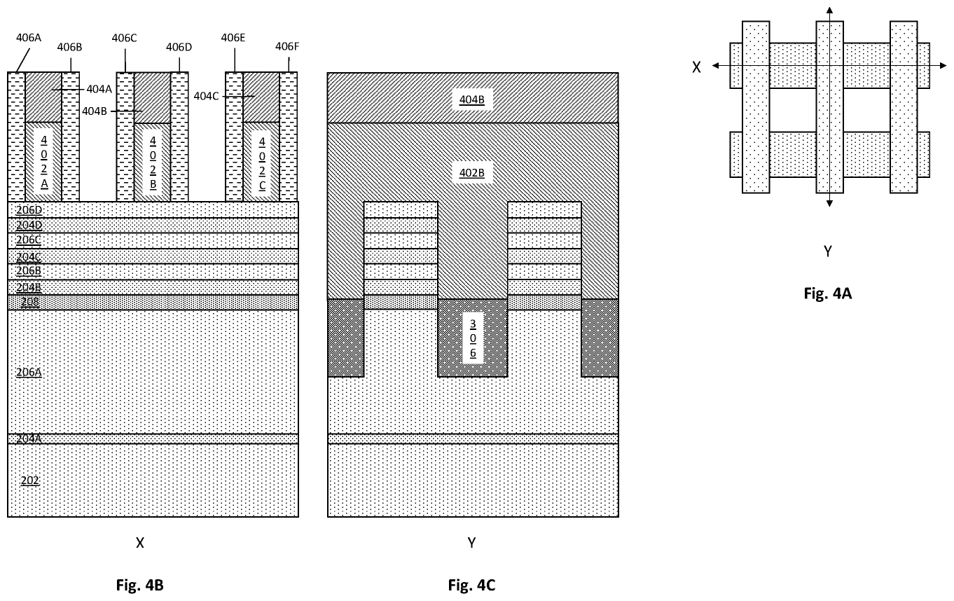

FIGS. 4A, 4B, and 4C illustrate a top view and cross-sectional views of a semiconductor structure under fabrication, according to one embodiment. FIG. 4A illustrates a top view of the semiconductor structure. In the illustrated embodiment, cross-section indicator X is shown traversing an active region of the semiconductor structure along an x-axis. Cross-section indicator Y is shown traversing a gate region of the semiconductor structure along the y-axis.

FIG. 4B illustrates a cross-section of the semiconductor structure at cross-section indicator X. In the illustrated embodiment, dummy gate material is deposited over layer 10 of the semiconductor structure to form dummy gates 402A-402C. The dummy gate material can include a thin layer of SiO₂ and polysilicon. A planarization process can be performed to form a level topside of the dummy gates 402A-402C.

Afterwards, hardmasks 404A-404C can be deposited over the dummy gates 402A-402C. In one embodiment, the hardmasks 404A-404C are deposited via chemical or physical vapor deposition process. The hardmasks 404A-404C can include materials such as Si₃N₄, amorphous carbon, SiO₂ or the like. An etching process can be performed to form sides of the dummy gates 402A-402C, and sides of the hardmasks 404A-404C.

In one embodiment, dummy gate spacers 406A-406B are disposed on opposing sides of dummy gate 402A and hardmask 404A. Dummy gate spacers 406C-406D are disposed on opposing sides of dummy gate 402B and hardmask 404B. Dummy gate spacers 406E-406F are disposed on opposing sides of dummy gate 402C and hardmask 404C. In one embodiment, the spacer material includes dielectrics such as silicon nitride (Si₃N₄), silicon dioxide (SiO₂), silicon oxynitride (SiOₓN_{y}), or the like.

FIG. 4C illustrates a cross-section of the semiconductor structure at cross-section indicator Y. In the illustrated embodiment, dummy gate 402B is disposed on the fin structures 304A-304B and the shallow trench isolation material 306. Hardmask 404B can be disposed on the dummy gate 402B.

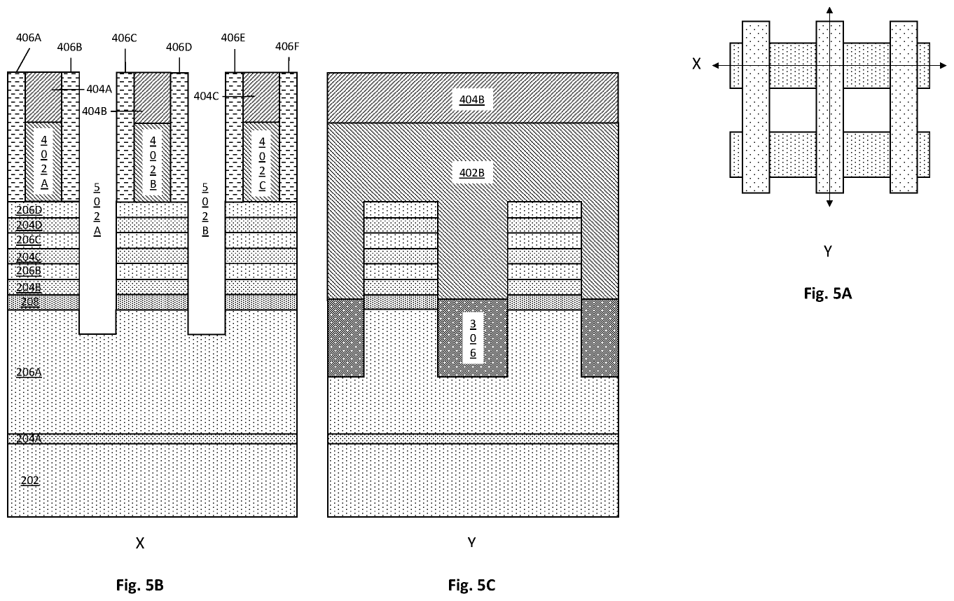

FIGS. 5A, 5B, and 5C illustrate a top view and cross-sectional views of a semiconductor structure under fabrication, according to one embodiment. FIG. 5A illustrates a top view of the semiconductor structure. In the illustrated embodiment, cross-section indicator X is shown traversing an active region of the semiconductor structure along an x-axis. Cross-section indicator Y is shown traversing a gate region of the semiconductor structure along the y-axis.

FIG. 5B illustrates a cross-section of the semiconductor structure at cross-section indicator X. In the illustrated embodiment, an etching process is performed to form a second set of trenches 502A-502B that extends from a topside of adjacent spacers (e.g., dummy gate spacers 406B-406C for trench 502A, and dummy gate spacers 406D-406E for trench 502B), through layers 4-10 of the semiconductor structure, and through a portion of layer 3 of the semiconductor structure.

It is contemplated that the fourth layer can be replaced by spacer material before forming the second set of trenches 502A-502B. However, such spacer material can slow the etching process that forms the second set of trenches 502A-502B. During this lengthened etching process, portions of the hardmasks 404A-404C and dummy gate spacers 406A-406F can be damaged, which can reduce the structural integrity of gates formed in place of the dummy gates 402A-402C.

In one embodiment of the present disclosure, forming the second set of trenches 502A-502B without replacing the fourth layer with spacer material allows the trench-forming etching process to be performed with minimal loss to the hardmasks 404A-404C and dummy gate spacers 406A-406F. FIG. 5C illustrates a cross-section of the semiconductor structure at cross-section indicator Y.

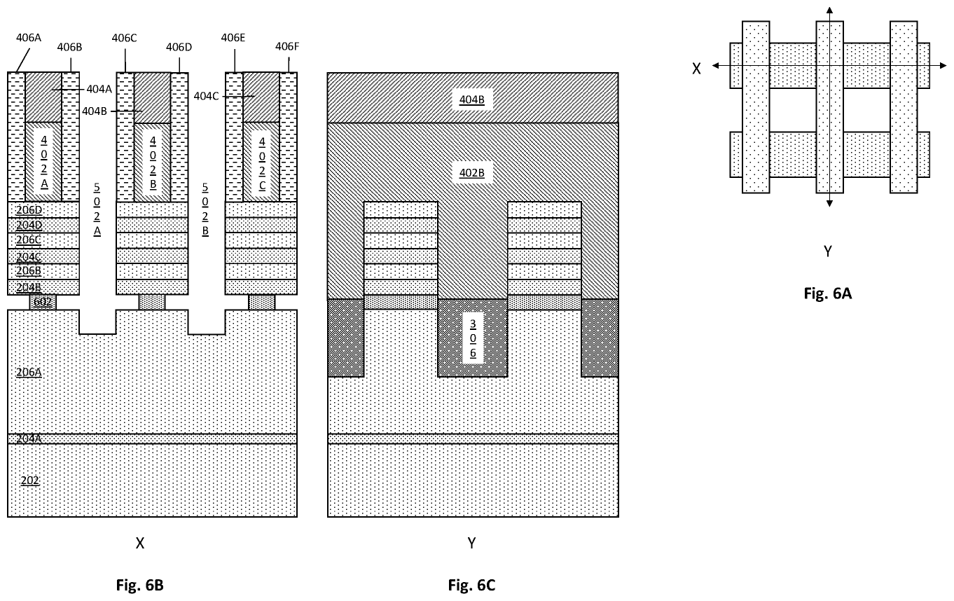

FIGS. 6A, 6B, and 6C illustrate a top view and cross-sectional views of a semiconductor structure under fabrication, according to one embodiment. FIG. 6A illustrates a top view of the semiconductor structure. In the illustrated embodiment, cross-section indicator X is shown traversing an active region of the semiconductor structure along an x-axis. Cross-section indicator Y is shown traversing a gate region of the semiconductor structure along the y-axis.

FIG. 6B illustrates a cross-section of the semiconductor structure at cross-section indicator X. In one embodiment, an etching process is performed remove portions of the fourth layer (e.g., the silicon etch stop layer 208), which form corresponding cavities in the fourth layer. FIG. 6C illustrates a cross-section of the semiconductor structure at cross-section indicator Y.

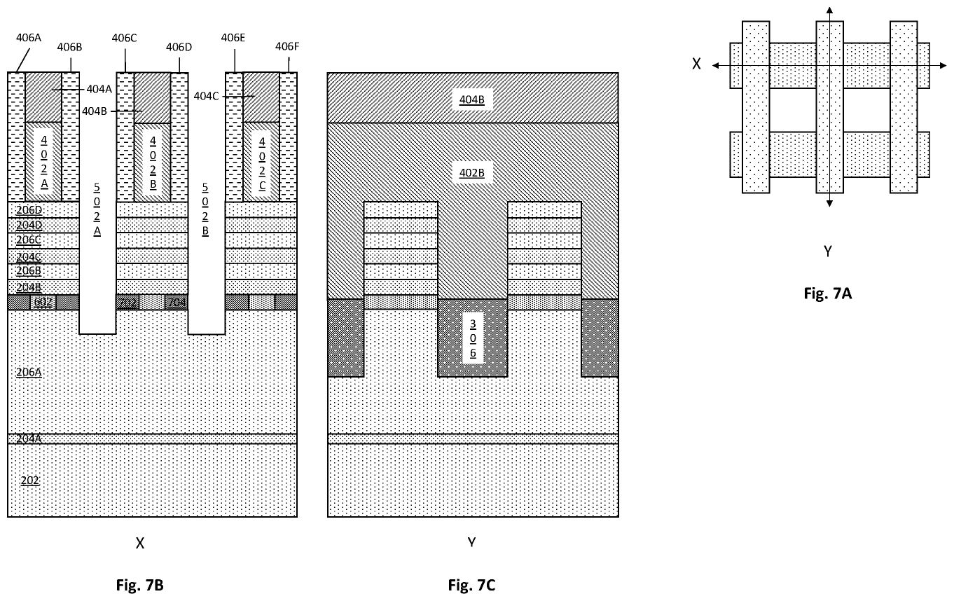

FIGS. 7A, 7B, and 7C illustrate a top view and cross-sectional views of a semiconductor structure under fabrication, according to one embodiment. FIG. 7A illustrates a top view of the semiconductor structure. In the illustrated embodiment, cross-section indicator X is shown traversing an active region of the semiconductor structure along an x-axis. Cross-section indicator Y is shown traversing a gate region of the semiconductor structure along the y-axis.

FIG. 7B illustrates a cross-section of the semiconductor structure at cross-section indicator X. In the illustrated embodiment, the cavities formed in the fourth layer are filled with spacer material. In one embodiment, this process is performed to form a first inner spacer 702 and a second inner spacer 704 in the fourth layer, between the second set of trenches 502A-502B. FIG. 7C illustrates a cross-section of the semiconductor structure at cross-section indicator Y.

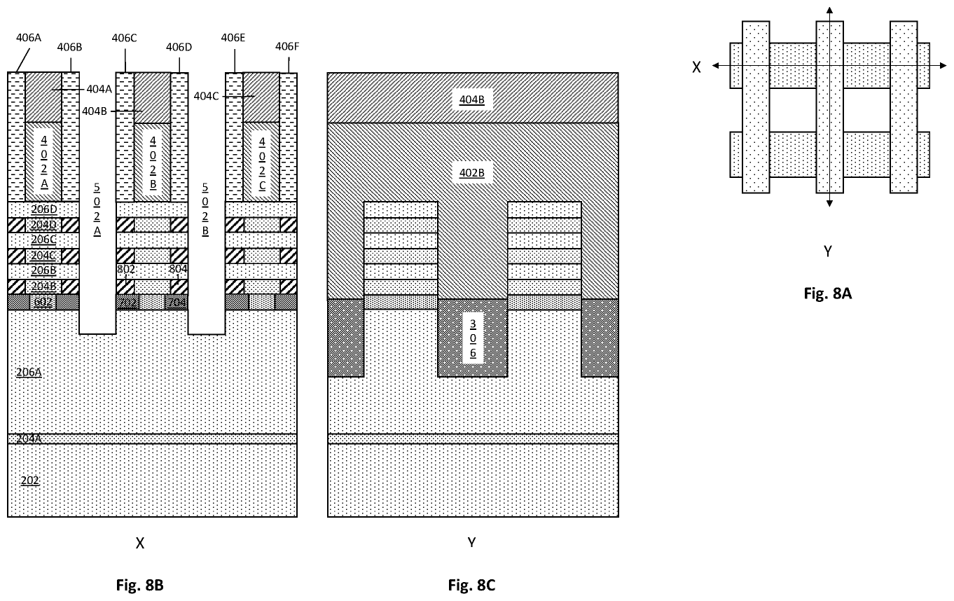

FIGS. 8A, 8B, and 8C illustrate a top view and cross-sectional views of a semiconductor structure under fabrication, according to one embodiment. FIG. 8A illustrates a top view of the semiconductor structure. In the illustrated embodiment, cross-section indicator X is shown traversing an active region of the semiconductor structure along an x-axis. Cross-section indicator Y is shown traversing a gate region of the semiconductor structure along the y-axis.

FIG. 8B illustrates a cross-section of the semiconductor structure at cross-section indicator X. In the illustrated embodiment, an etching process is performed to remove portions of layers 5, 7, and 9 (e.g., sacrificial layers 204B-204D). The removed portions form cavities that can be filled with spacer material. In one embodiment, this process is performed to form a third inner spacer 802 and a fourth inner spacer 804 in the fifth layer, between the second set of trenches 502A-502B. FIG. 8C illustrates a cross-section of the semiconductor structure at cross-section indicator Y.

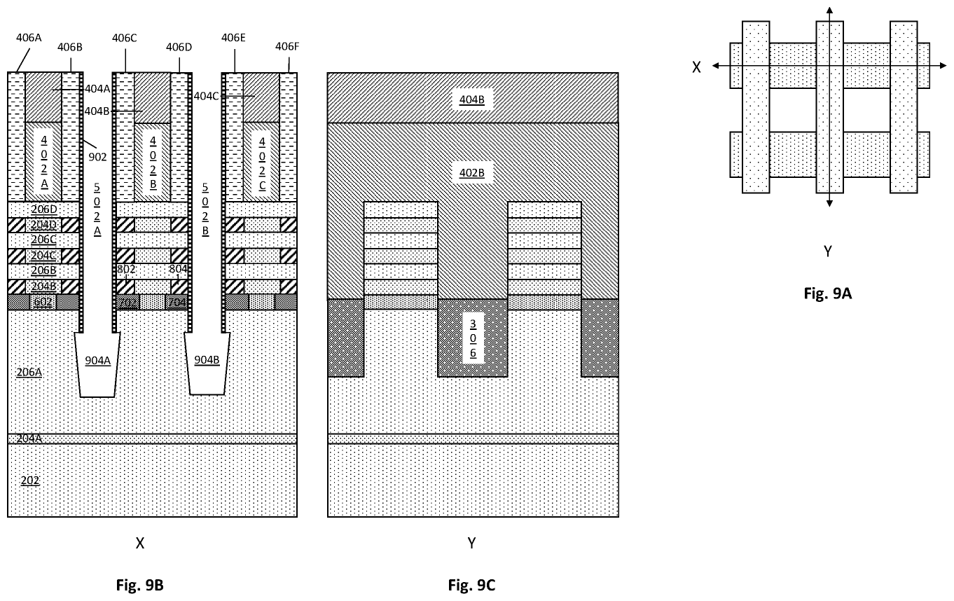

FIGS. 9A, 9B, and 9C illustrate a top view and cross-sectional views of a semiconductor structure under fabrication, according to one embodiment. FIG. 9A illustrates a top view of the semiconductor structure. In the illustrated embodiment, cross-section indicator X is shown traversing an active region of the semiconductor structure along an x-axis. Cross-section indicator Y is shown traversing a gate region of the semiconductor structure along the y-axis.

FIG. 9B illustrates a cross-section of the semiconductor structure at cross-section indicator X. In the illustrated embodiment, an etching process is performed to form a first silicon layer cavity 904A in trench 502A, and a second silicon layer cavity 904B in trench 502B. Further, protective spacer material 902 can be deposited on opposite sides of trench 502B and opposite sides of trench 502B. FIG. 9C illustrates a cross-section of the semiconductor structure at cross-section indicator Y.

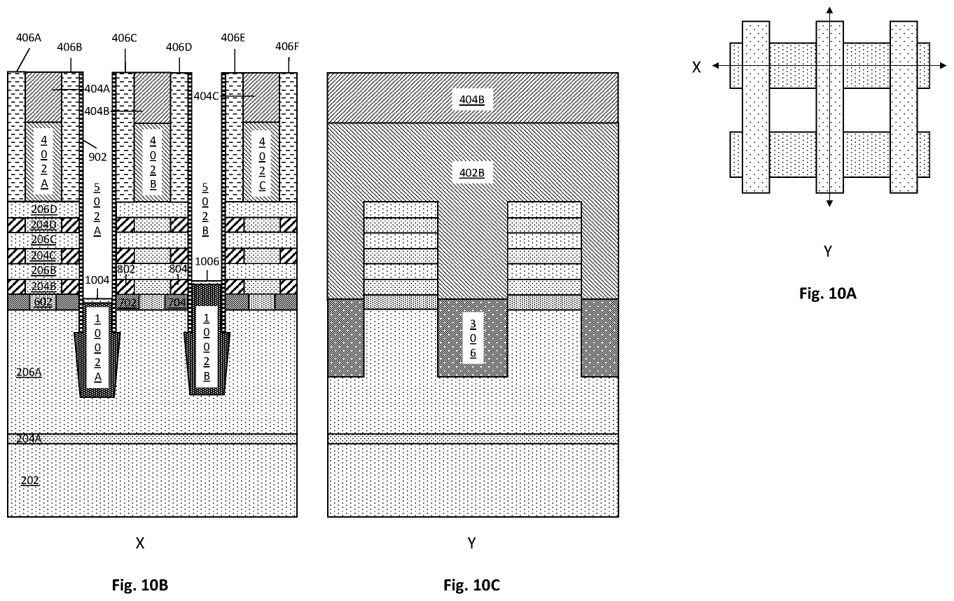

FIGS. 10A, 10B, and 10C illustrate a top view and cross-sectional views of a semiconductor structure under fabrication, according to one embodiment. FIG. 10A illustrates a top view of the semiconductor structure. In the illustrated embodiment, cross-section indicator X is shown traversing an active region of the semiconductor structure along an x-axis. Cross-section indicator Y is shown traversing a gate region of the semiconductor structure along the y-axis.

FIG. 10B illustrates a cross-section of the semiconductor structure at cross-section indicator X. In the illustrated embodiment, placeholders (e.g., a first placeholder 1002A and a second placeholder 1002B) are epitaxially grown and formed in the second set of trenches 502A-502B. The placeholders 1002A-1002B can include non-doped or intrinsic SiGe.

The placeholders can be grown to a level between a bottom surface of the first inner spacer 702 (or the second inner spacer 704) and an upper surface of the third inner spacer 802 (or the fourth inner spacer 804). Afterwards, a placeholder cap layer 1004 can be deposited and formed over the first placeholder 1002A, and a contact cap layer 1006 can be deposited and formed over the second placeholder 1002B. In one embodiment, the placeholder cap layer 1004 and the contact cap layer 1006 are silicon layers.

In this manner, the placeholder cap layer 1004, the contact cap layer 1006, and contacts formed in place of the placeholders 1002A-1002B can have an upper surface that falls between an upper surface of the third layer (e.g., the silicon layer 206A), and a bottom surface of the sixth layer (e.g., a nanosheet layer 206B). This disposition can prevent damage to a cap layer (e.g., placeholder cap layer 1004 or the contact cap layer 1006) and a source/drain region disposed on the cap layer during a removal of the third layer (e.g., silicon layer 206A). That is, if the cap layer is below a bottom surface of the first inner spacer 702 or the second inner spacer 704, then the cap layer may be connected to the third layer. Thus, if the third layer is removed, then portions of the cap layer and the source/drain region can also be removed, thereby affecting the functionality of the source/drain region.

Further, if the cap layer is above an upper surface of the third inner spacer 802 or the fourth inner spacer 804, then a source/drain region disposed on the cap layer may not fully connect to the sixth layer (e.g., nanosheet layer 206B), thereby impeding functionality of the source/drain region. FIG. 10C illustrates a cross-section of the semiconductor structure at cross-section indicator Y.

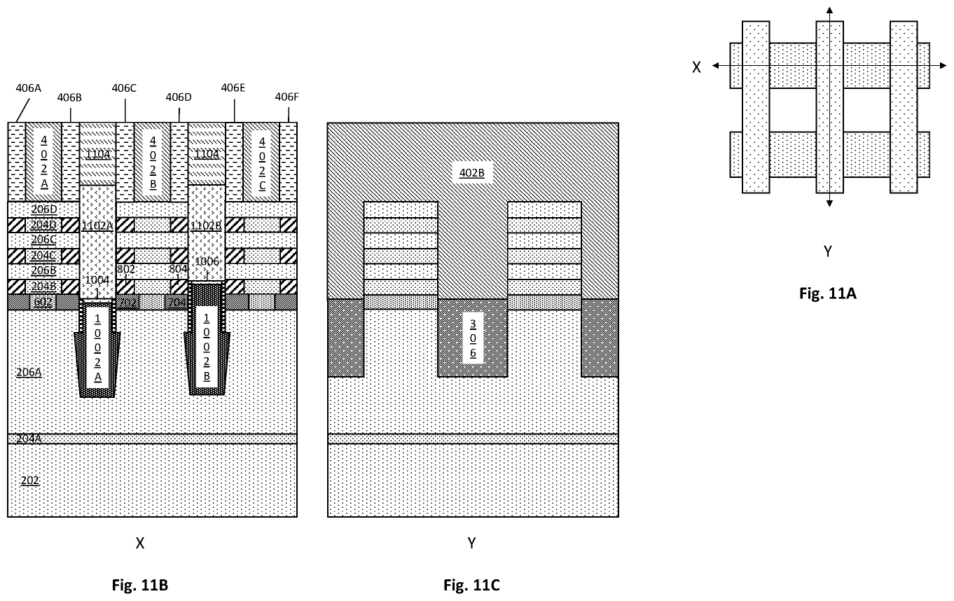

FIGS. 11A, 11B, and 11C illustrate a top view and cross-sectional views of a semiconductor structure under fabrication, according to one embodiment. FIG. 11A illustrates a top view of the semiconductor structure. In the illustrated embodiment, cross-section indicator X is shown traversing an active region of the semiconductor structure along an x-axis. Cross-section indicator Y is shown traversing a gate region of the semiconductor structure along the y-axis.

FIG. 11B illustrates a cross-section of the semiconductor structure at cross-section indicator X. In the illustrated embodiment, an etching process is performed to remove portions of the protective spacer material 902 in the second set of trenches 502A-502B, such that remaining portions of the protective spacer material 902 are level with a top surface of the placeholder cap layer 1004 or the contact cap layer 1006.

Source/drain regions 1102A-1102B can be epitaxially grown and formed over the placeholder cap layer 1004, contact cap layer 1006, and the remaining portions of the protective spacer material 902. In one embodiment, the source/drain regions 510A-510B include doped silicon, doped SiGe, or the like.

Interlayer dielectric (ILD) material 1104 can then be deposited over the source/drain regions 1102A-1102B. Afterwards, etching processes and planarization processes can be performed to remove the hardmasks 404A-404C, and level a topside of the dummy gate spacers 406A-406F and the ILD material 1104 with an upper surface of the dummy gates 402A-402C.

FIG. 11C illustrates a cross-section of the semiconductor structure at cross-section indicator Y. The illustrated embodiment reflects the removal of hardmask 404B.

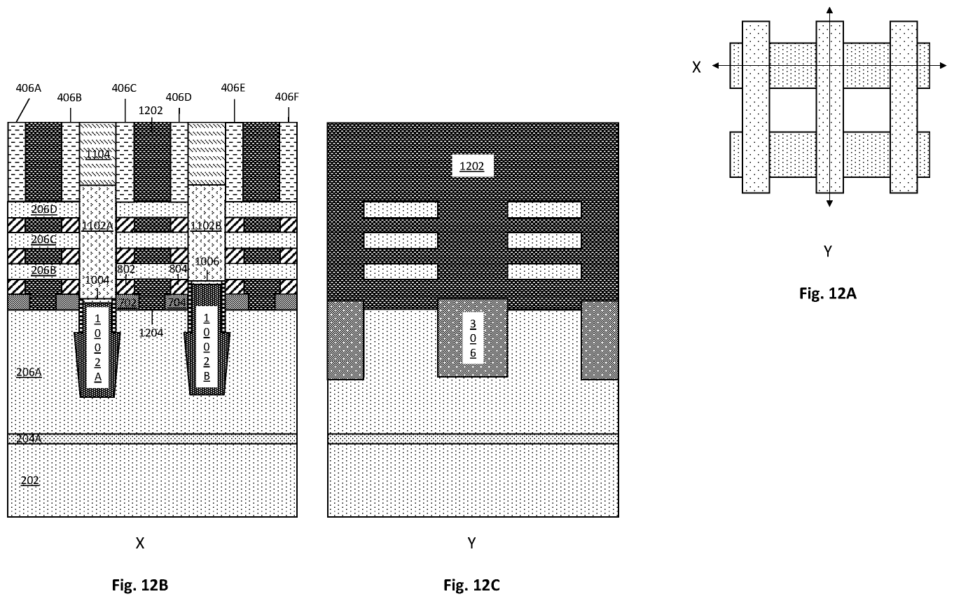

FIGS. 12A, 12B, and 12C illustrate a top view and cross-sectional views of a semiconductor structure under fabrication, according to one embodiment. FIG. 2A illustrates a top view of the semiconductor structure. In the illustrated embodiment, cross-section indicator X is shown traversing an active region of the semiconductor structure along an x-axis. Cross-section indicator Y is shown traversing a gate region of the semiconductor structure along the y-axis.

FIG. 12B illustrates a cross-section of the semiconductor structure at cross-section indicator X. In the illustrated embodiment, etching processes can be performed to remove the dummy gates 402A-402C and the remaining portions of layers 4, 5, 7, and 9 (e.g., the recessed silicon etched stop layer 602, and the sacrificial layers 204B-204D).

Further, the high-k metal gate material 1202 can be deposited into spaces formed by the removal of the dummy gates 402A-402C and layers 4, 5, 7, and 9. Afterwards, a planarization process can be performed to level a topside of the dummy gate spacers 406A-406F, the high-k metal gate material 1202, and the ILD material 1104.

In this manner, the high-k metal gate material 1202 can form a T-shaped gate region 1204 at between the third layer (e.g., the silicon layer 206A) and the sixth layer (e.g., nanosheet layer 206B). The structure of the T-shaped gate region 1204 can be provided by the first inner spacer 702, the second inner spacer 704, the third inner spacer 802, and the fourth inner spacer 804. In one embodiment, the first inner spacer 702 and the second inner spacer 704 reduce the gate distance at the bottom of the T-shaped gate region 1204, which can reduce parasitic capacitance between the T-shaped gate region 1204 and the source/drain regions 1102A-1102B.

FIG. 12C illustrates a cross-section of the semiconductor structure at cross-section indicator Y. In the illustrated embodiment, nanosheets are formed as a result of the removal of portions of layers 5, 7, and 9 (e.g., the sacrificial layers 204B-204D) of the semiconductor structure. Further, the high-k metal gate material 1202 is shown as being deposited over the layers 3, 6, 8, 10 (e.g., the silicon layer 206A, and the nanosheet layers 206B-206D), and the shallow trench isolation material 306 of the semiconductor structure.

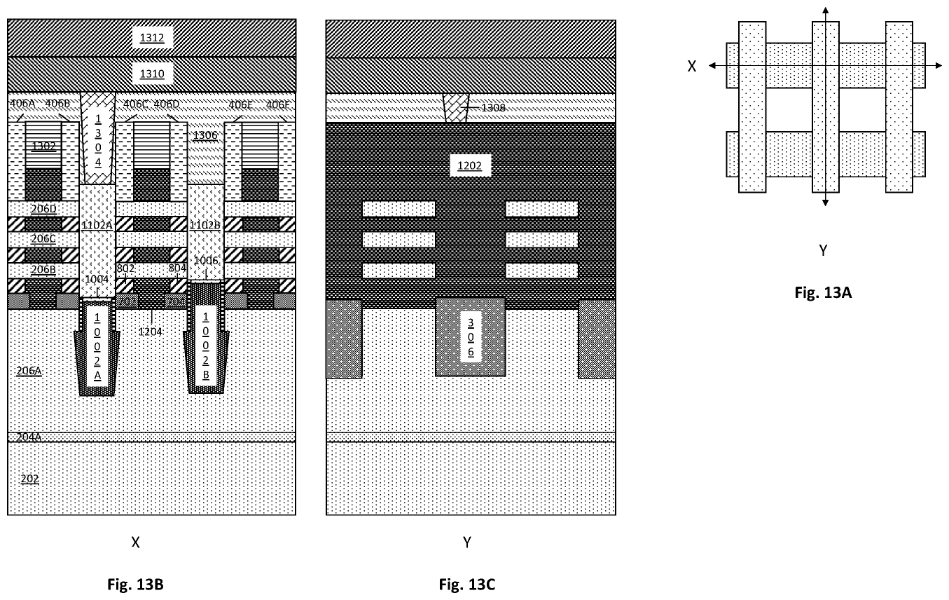

FIGS. 13A, 13B, and 13C illustrate a top view and cross-sectional views of a semiconductor structure under fabrication, according to one embodiment. FIG. 13A illustrates a top view of the semiconductor structure. In the illustrated embodiment, cross-section indicator X is shown traversing an active region of the semiconductor structure along an x-axis. Cross-section indicator Y is shown traversing a gate region of the semiconductor structure along the y-axis.

FIG. 13B illustrates a cross-section of the semiconductor structure at cross-section indicator X. In the illustrated embodiment, self-aligned gate cap material 1302 is deposited over the high-k metal gate material 1202 positioned between paired dummy gate spacers (e.g., dummy gate spacers 406A-406B, dummy gate spacers 406C-406D, and dummy gate spacers 406E-406F).

In one embodiment, a frontside source/drain contact 1304 is disposed on a frontside of the first source/drain region 1102A. The frontside source/drain contact 1304 can include a silicide liner (e.g., Ti, Ni, NiPt, etc.), an adhesion metal liner (e.g., TiN, TaN, etc.), low resistance metal fill (e.g., W, Co, Ru, etc.), or the like. Other contacts can be added to the semiconductor structure as described, e.g., in FIG. 7C herein.

Afterwards, additional ILD material can be deposited over the dummy gate spacers 406A-406F, the high-k metal gate material 1202, and the present ILD material 1104 to form a frontside ILD layer 1306. In one embodiment, the additional ILD material includes a same or different material composition than ILD material 1104. A back-end-of-line (BEOL) interconnect 1310 can then be disposed on the contacts and the frontside ILD layer 1306 to connect the semiconductor structure to an integrated circuit. Further, a carrier wafer bonding process can be performed to connect the BEOL interconnect 1310 to a carrier wafer 1312.

FIG. 13C illustrates a cross-section of the semiconductor structure at cross-section indicator Y. In the illustrated embodiment, gate contact 1308 is disposed on the high-k metal gate material 1202. Further, the BEOL interconnect 1310 is shown as being disposed on gate contact 1308 and the frontside ILD layer 1306. The carrier wafer 1312 is shown as being disposed on the BEOL interconnect 1310.

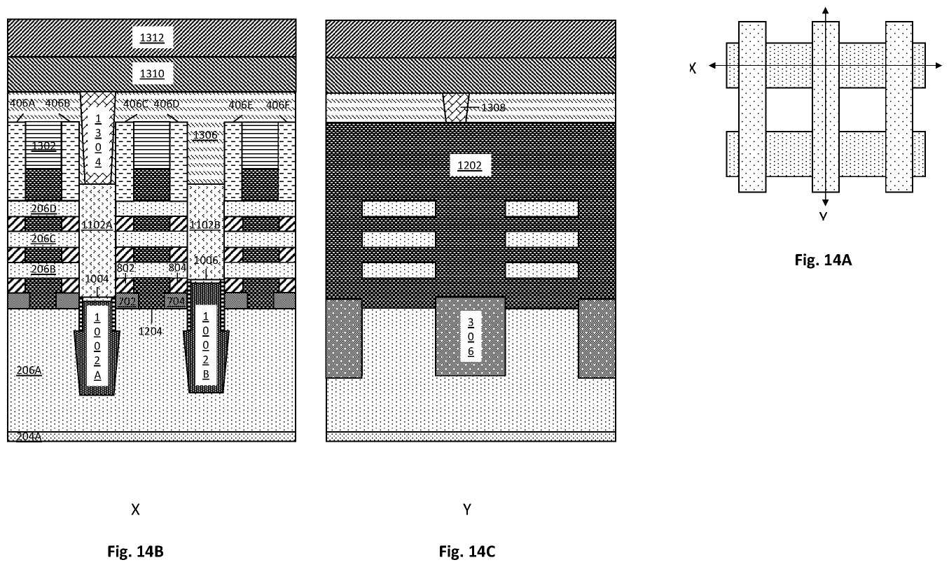

FIGS. 14A, 14B, and 14C illustrate a top view and cross-sectional views of a semiconductor structure under fabrication, according to one embodiment. FIG. 14A illustrates a top view of the semiconductor structure. In the illustrated embodiment, cross-section indicator X is shown traversing an active region of the semiconductor structure along an x-axis. Cross-section indicator Y is shown traversing a gate region of the semiconductor structure along the y-axis. FIG. 14B illustrates a cross-section of the semiconductor structure at cross-section indicator X. FIG. 14C illustrates a cross-section of the semiconductor structure at cross-section indicator Y.

In one embodiment, the semiconductor structure is flipped to provide access to further process the silicon substrate 202. However, for consistency in the illustrations, the illustrated embodiment retains the orientation of the semiconductor structure from the preceding figures. In one embodiment, layer 1 (e.g., the silicon substrate 202) of the semiconductor structure is removed, which exposes layer 2 (e.g., sacrificial layer 204A) of the semiconductor structure.

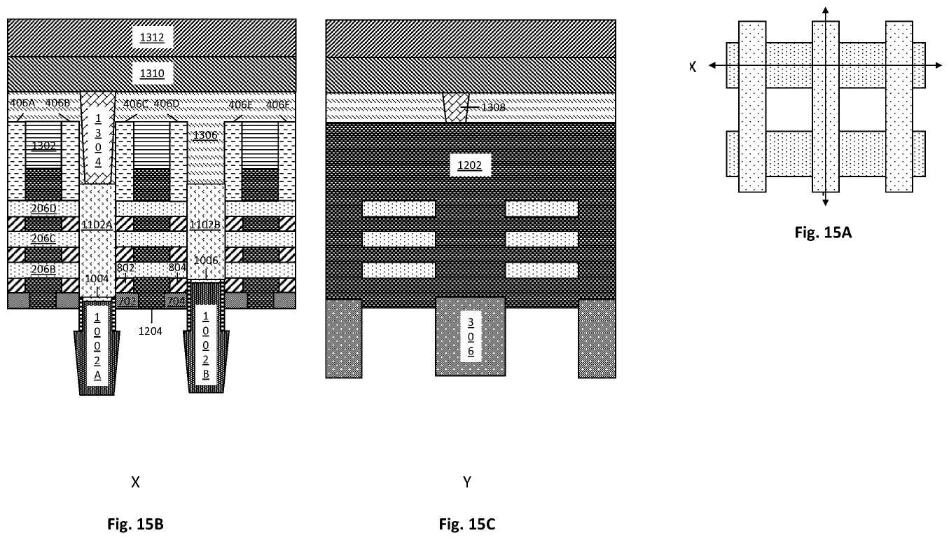

FIGS. 15A, 15B, and 15C illustrate a top view and cross-sectional views of a semiconductor structure under fabrication, according to one embodiment. FIG. 15A illustrates a top view of the semiconductor structure. In the illustrated embodiment, cross-section indicator X is shown traversing an active region of the semiconductor structure along an x-axis. Cross-section indicator Y is shown traversing a gate region of the semiconductor structure along the y-axis. FIG. 15B illustrates a cross-section of the semiconductor structure at cross-section indicator X. FIG. 15C illustrates a cross-section of the semiconductor structure at cross-section indicator Y.

In one embodiment, an etching process is performed to remove layer 2 (e.g., sacrificial layer 204A) of the semiconductor structure. Further, an etching process can be performed to recess layer 3 (e.g., silicon layer 206A), and expose the placeholders 1002A-1002B, the first inner spacer 702, the second inner spacer 704, the shallow trench isolation material 306, and a bottom surface of the high-k metal gate material 1202. The material compositions of the placeholders 1002A-1002B can prevent the placeholders 1002A-1002B from being etched.

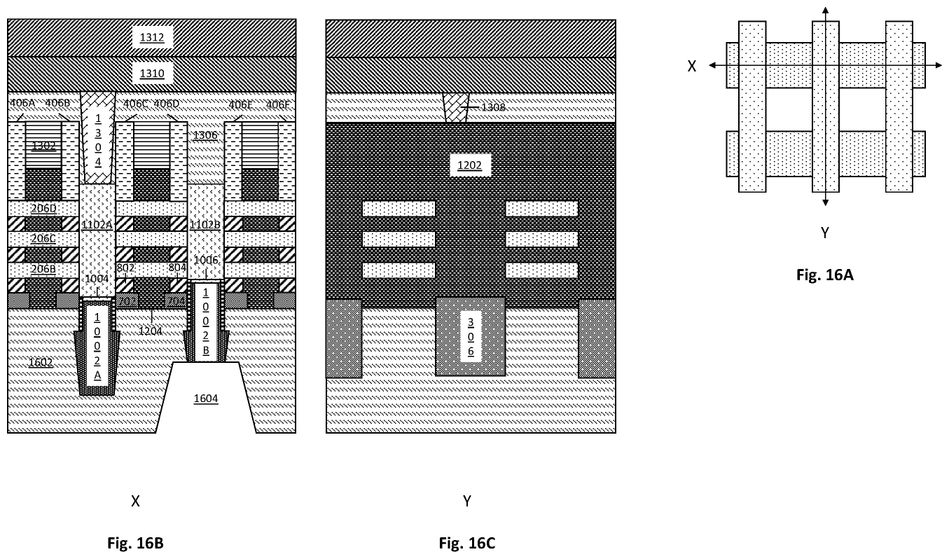

FIGS. 16A, 16B, and 16C illustrate a top view and cross-sectional views of a semiconductor structure under fabrication, according to one embodiment. FIG. 16A illustrates a top view of the semiconductor structure. In the illustrated embodiment, cross-section indicator X is shown traversing an active region of the semiconductor structure along an x-axis. Cross-section indicator Y is shown traversing a gate region of the semiconductor structure along the y-axis. FIG. 16B illustrates a cross-section of the semiconductor structure at cross-section indicator X. FIG. 16C illustrates a cross-section of the semiconductor structure at cross-section indicator Y.

In one embodiment, additional ILD material is deposited on the first inner spacer material, a bottom surface of the high-k metal gate material 1102, and a bottom surface of the second placeholder 1002B to form a backside ILD layer 1602. Afterwards, an etching process can be performed to form a backside contact pattern recess 1604 in the backside ILD layer 1602 at the second placeholder 1002B.

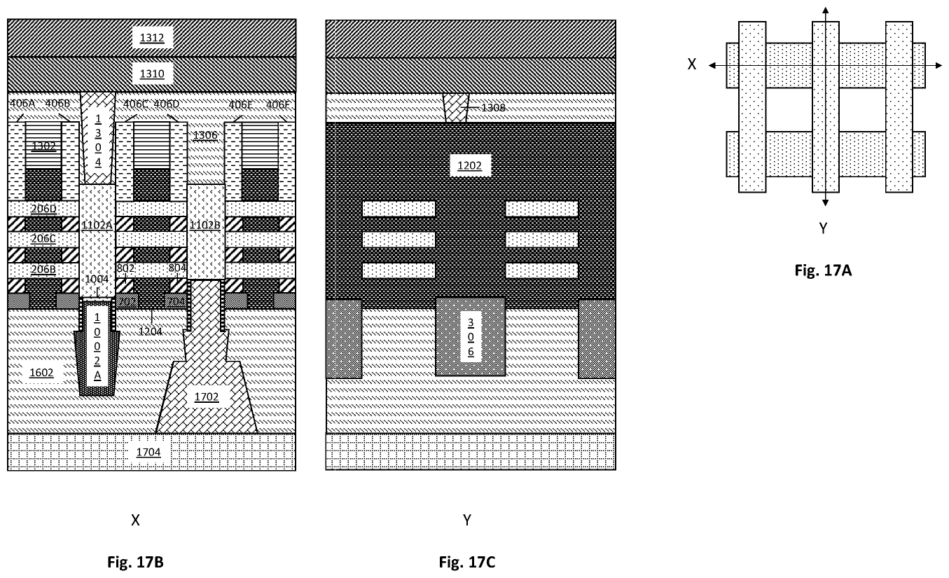

FIGS. 17A, 17B, and 17C illustrate a top view and cross-sectional views of a semiconductor structure under fabrication, according to one embodiment. FIG. 17A illustrates a top view of the semiconductor structure. In the illustrated embodiment, cross-section indicator X is shown traversing an active region of the semiconductor structure along an x-axis. Cross-section indicator Y is shown traversing a gate region of the semiconductor structure along the y-axis.

FIG. 17B illustrates a cross-section of the semiconductor structure at cross-section indicator X. FIG. 17C illustrates a cross-section of the semiconductor structure at cross-section indicator Y.

In one embodiment, the second placeholder 1002B and the contact cap layer 1006 are removed. A backside source/drain contact 1702 can then be formed in a space that includes the backside contact pattern recess 1604, and a cavity created by the removal of the second placeholder 1002B and the contact cap layer 1006. In this manner, the second source/drain region 1102B is disposed on the backside source/drain contact 1702. Afterwards, a backside interconnect layer 1704 can be disposed on a bottom surface of the backside ILD layer 1602 and a bottom surface of the backside source/drain contact 1702.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that some of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

Embodiments of the present disclosure may reference an interlayer dielectric (ILD) material. The ILD material can be an insulating material used to electrically isolate different layers of a semiconductor structure. The ILD material can be SiO₂, SiN, a low-k dielectric material, or an ultra-low-k dielectric material. Low-k dielectric materials may generally include dielectric materials having a k value of about 3.9 or less. The ultralow-k dielectric material generally includes dielectric materials having a k value less than 2.5. Unless otherwise noted, all k values mentioned in the present application are measured relative to a vacuum. Ultra-low-k dielectric materials can include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process. In the templated process, a precursor typically contains a composite of thermally labile and stable materials. After film deposition, the thermally labile materials can be removed by thermal heating, leaving pores in the dielectric film. In the sol gel process, porous low-k dielectric films can be formed by hydrolysis and polycondensation of an alkoxide(s) such as tetraetehoxysilane (TEOS).

Embodiments of the present disclosure may reference p-type or n-type semiconductor structures. “P-type” can refer to the addition of impurities to an intrinsic semiconductor that creates deficiencies of valence electrons. In a silicon-containing substrate, examples of p-type dopants (i.e., impurities) include, but are not limited to, boron, aluminum, gallium and indium. “N-type” can refer to the addition of impurities that contributes free electrons to an intrinsic semiconductor. In a silicon containing substrate examples of n-type dopants (i.e., impurities) include, but are not limited to, antimony, arsenic and phosphorous.

Various processes used to form a semiconductor structure that will be packaged into an IC fall into four general categories: film deposition, removal/etching, semiconductor doping and patterning/lithography. Deposition is any process that grows, coats, or otherwise transfers a material onto the wafer. Examples of such technologies include physical vapor deposition (PVD), chemical vapor deposition (CVD), plasma enhanced chemical vapor deposition (PECVD), electrochemical deposition (ECD), atomic layer deposition (ALD), epitaxial growth/deposition, or the like. The term “epitaxial growth/deposition” may reference growth of a first semiconductor material on a surface of a second semiconductor material, in which the first semiconductor material has the same crystalline characteristics as the surface of the second semiconductor material. In an epitaxial growth process, chemical reactants provided by source gases are controlled, and system parameters are set so that deposited atoms are disposed on the surface of the second semiconductor material with sufficient energy to traverse the surface and orient to a crystal arrangement of atoms of the surface. Examples of epitaxial growth/deposition process techniques include rapid thermal chemical vapor deposition (RTCVD), low-energy plasma deposition (LEPD), ultra-high vacuum chemical vapor deposition (UHVCVD), atmospheric pressure chemical vapor deposition (APCVD), molecular beam epitaxy (MBE), or the like.

Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., polysilicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, transistors can be built and wired together to form the circuitry of a modern semiconductor device.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation, or the like. Afterwards, the exposed photoresist is developed utilizing a conventional resist development process.

Following the development step, the etching step can be performed to transfer the pattern from the patterned photoresist into the interlayer dielectric. The etching step used in forming the at least one opening can include a dry etching process (e.g., reactive ion etching, ion beam etching, plasma etching, or laser ablation), a wet chemical etching process, or any combination thereof.

While the foregoing is directed to embodiments of the present disclosure, other and further embodiments of the present disclosure may be devised without departing from the basic scope thereof, and the scope thereof is determined by the claims that follow.

1. A semiconductor structure, comprising:
a first inner spacer and a second inner spacer disposed on a silicon layer;
a third inner spacer disposed on the first inner spacer;
a fourth inner spacer disposed on the second inner spacer;
a gate region disposed on the silicon layer; and
a source/drain region disposed on a backside source/drain contact, wherein an upper surface of the backside source/drain contact is disposed above a bottom surface of the first inner spacer or the second inner spacer, and wherein the upper surface of the backside source/drain contact is disposed below an upper surface of the third inner spacer or the fourth inner spacer.

2. The semiconductor structure of claim 1, wherein the gate region is a T-shaped gate region formed by the first inner spacer, the second inner spacer, the third inner spacer, and the fourth inner spacer.

3. The semiconductor structure of claim 2, wherein the first inner spacer and the second inner spacer are disposed on a same level of the semiconductor structure, and wherein the first inner spacer and the second inner spacer form a bottom region of the T-shaped gate region.

4. The semiconductor structure of claim 3, wherein the third inner spacer and the fourth inner spacer are disposed on another same level of the semiconductor structure, and wherein the third inner spacer and the fourth inner spacer form a top region of the T-shaped gate region.

5. The semiconductor structure of claim 4, wherein the top region of the T-shaped gate region is wider than the bottom region of the T-shaped gate region.

6. The semiconductor structure of claim 1, wherein the backside source/drain contact is isolated from the T-shaped gate region via the second inner spacer and the fourth inner spacer.

7. The semiconductor structure of claim 1, further comprising:
a nanosheet disposed on the T-shaped gate region, the third inner spacer, and the fourth inner spacer.

8. The semiconductor structure of claim 1, further comprising:
another source/drain region disposed on a placeholder, wherein an upper surface of the placeholder is disposed above a bottom surface of the first inner spacer or the second inner spacer, and wherein the upper surface of the placeholder is disposed below an upper surface of the third inner spacer or the fourth inner spacer.

9. The semiconductor structure of claim 8, wherein the placeholder is separated from the T-shaped gate region via the first inner spacer and the third inner spacer.

10. The semiconductor structure of claim 8, wherein the placeholder and the backside source/drain contact are disposed in a backside interlayer dielectric (ILD) layer;
wherein the backside ILD layer is disposed on a backside interconnect;
wherein a frontside source/drain contact is disposed on the another source/drain region;
wherein a frontside ILD layer is disposed on the source/drain region, a self-aligned gate cap, and a plurality of gate spacers;
wherein a back-end-of-line interconnect is disposed on the frontside source/drain contact; and
wherein a carrier wafer is bonded to the back-end-of-line interconnect.

11. A method comprising:
forming a set of trenches in a semiconductor structure;
forming a first inner spacer and a second inner spacer in the set of trenches;
forming a third inner spacer and a fourth inner spacer in the set of trenches, wherein the third inner spacer is disposed on the first inner spacer, and wherein the fourth inner spacer is disposed on the second inner spacer; and
forming a backside source/drain contact in the set of trenches, wherein an upper surface of the backside source/drain contact is disposed above a bottom surface of the first inner spacer or the second inner spacer, and wherein the upper surface of the backside source/drain contact is disposed below an upper surface of the third inner spacer or the fourth inner spacer.

12. The method of claim 11, wherein the semiconductor structure includes:
a silicon substrate;
a first sacrificial layer disposed on the silicon substrate, wherein the first sacrificial layer includes SiGe25%;
a silicon layer disposed on the first sacrificial layer;
a silicon etch stop layer disposed on the silicon layer, wherein the silicon etch stop includes SiGe55%;
a second sacrificial layer disposed on the silicon etch stop;
a first nanosheet layer disposed on the second sacrificial layer;
a third sacrificial layer disposed on the first nanosheet layer;
a second nanosheet layer disposed on the third sacrificial layer;
a fourth sacrificial layer disposed on the second nanosheet layer; and
a third nanosheet layer disposed on the fourth sacrificial layer.

13. The method of claim 12, wherein the first inner spacer and the second inner spacer are formed in the silicon etch stop layer.

14. The method of claim 12, wherein the third inner spacer and the fourth inner spacer are formed in the second sacrificial layer.

15. The method of claim 11, further comprising:
depositing a high-k metal gate material between the first inner spacer and the second inner spacer; and
depositing the high-k metal gate material between the third inner spacer and the fourth inner spacer.

16. The method of claim 15, wherein the high-k metal gate material forms a T-shaped gate region.

17. The method of claim 16, wherein the backside source/drain contact is isolated from the T-shaped gate region via the second inner spacer and the fourth inner spacer.

18. The method of claim 16, wherein the high-k metal gate material between the first inner spacer and the second inner spacer forms a bottom region of the T-shaped gate region.

19. The method of claim 18, wherein the high-k metal gate material between the third inner spacer and the fourth inner spacer forms a top region of the T-shaped gate region.

20. The method of claim 19, wherein the top region of the T-shaped gate region is wider than the bottom region of the T-shaped gate region.
